(19) United States
(12) Patent Application Publication
(10) Pub. No.: US 2025/0220932 A1
(43) Pub. Date: Jul. 3, 2025

(54) DEFECT SELF-COMPENSATION MATERIALS FOR HIGH ENDURANCE (ANTI-)FERROELECTRIC CAPACITORS WITH HAFNIUM OXIDE BASED MATERIAL SYSTEMS

(71) Applicant: Intel Corporation, Santa Clara, CA (US)

(72) Inventors: Sou-Chi Chang, Portland, OR (US); Sarah Atanasov, Beaverton, OR (US); Bernal Granados Alpizar, Beaverton, OR (US); Christopher Jezewski, Portland, OR (US); Christopher Neumann, Portland, OR (US); Uygar Avci, Portland, OR (US); Nazila Haratipour, Portland, OR (US)

(73) Assignee: Intel Corporation, Santa Clara, CA (US)

(21) Appl. No.: 18/400,895

(22) Filed: Dec. 29, 2023

(51) Int. Cl. H10B 53/20; H10B 53/30

(52) U.S. Cl. CPC H10D 1/692; H10B 53/20; H10B 53/30

(57) ABSTRACT

Apparatuses, systems, and techniques related to ferroelectric material systems including hafnium oxide-based ferroelectric layers are described. A ferroelectric material system includes a hafnium oxide-based ferroelectric layer and a defect compensation material on the hafnium oxide-based ferroelectric layer. The defect compensation material is an oxide having a stronger bound dissociation energy relative to the hafnium oxide-based ferroelectric layer to compensate for oxygen defects formed in the hafnium oxide-based ferroelectric layer.

### BACKGROUND

(Anti-)Ferroelectric memory devices such as random-access memory (RAM) use ferroelectric materials in place of the dielectric material deployed in the capacitor of a typical dynamic random-access memory (DRAM). Such ferroelectric memory devices have promising characteristics such as lower power usage, fast write performance, and others. In particular, hafnia-based material systems are of interest in such memory devices due to their performance characteristics, compatibility with existing complementary metal-oxide semiconductor (CMOS) technology, and others. Such hafnia-based memory devices require being functional after >10¹³ read and write cycles for cache-level applications. However, defects (e.g., oxygen vacancy defects) generated in the devices during field cycling as well as those present when the devices are fabricated cause difficulties in meeting the required read and write cycle endurance. These defects serve as pinning sites to reduce the amount of switched polarization (memory window), and therefore degrade the endurance (reliability) of the device. Therefore, material systems that meet the required endurance are needed.

It is with respect to these and other considerations that the present improvements have been needed. Such improvements may become critical as the desire to deploy advanced memory solutions becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a schematic of an example ferroelectric capacitor;

FIG. 1B illustrates a diagram of an example memory cell circuit;

FIG. 1C illustrates a plot showing polarization versus voltage for a capacitor deploying a ferroelectric material;

FIG. 1D illustrates a plot showing polarization versus voltage for a capacitor deploying an anti-ferroelectric material;

FIG. 1E illustrates a plot showing polarization versus voltage for a capacitor deploying an anti-ferroelectric material after voltage shift;

FIG. 2 illustrates a cross-sectional side view of an example ferroelectric device structure having a defect compensation layer on each side of a ferroelectric hafnium oxide-based material layer;

FIG. 3 illustrates a cross-sectional side view of an example ferroelectric device structure having a defect compensation layer between a ferroelectric hafnium oxide-based material layer and a bottom electrode;

FIG. 4 illustrates a cross-sectional side view of an example ferroelectric device structure having a defect compensation layer between a ferroelectric hafnium oxide-based material layer and a top electrode;

FIG. 5 illustrates a cross-sectional side view of an example ferroelectric device structure having a defect compensation layer between a ferroelectric hafnium oxide-based material layer and a top electrode and the ferroelectric hafnium oxide-based material layer on a seed layer;

FIG. 6 illustrates a cross-sectional side view of an exemplary deep trench capacitor having a defect compensation layer on at least one side of a ferroelectric hafnium oxide-based material layer;

FIG. 7 illustrates a cross-section of an embedded dynamic random-access memory including the capacitor of FIG. 6;

FIG. 8 illustrates a cross-sectional side view of a multiple capacitor stacked memory device including capacitors having a defect compensation layer on at least one side of a ferroelectric hafnium oxide-based material layer;

FIG. 9 is a flow diagram illustrating methods for forming a device including a defect compensation layer on at least one side of a ferroelectric hafnium oxide-based material layer;

FIGS. 10A, 10B, 10C, 10D, 10E, 10F, and 10G are cross-sectional views of a device structure evolving as the methods of FIG. 9 are practiced;

FIG. 11 illustrates exemplary systems employing an IC die having a defect compensation layer on a ferroelectric hafnium oxide-based layer;

FIG. 12 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 95% of the particular material or component and the term “pure” indicates not less than 99% of the particular material or component. Furthermore, such terms may be used to indicate a material is not less than 50%, not less than 95%, or not less than 99% of a multi-component (i.e., two or more component system). Unless otherwise indicated, such material percentages are based on atomic percentage. As used herein, the terms “monolithic”, “monolithically integrated”, and similar terms indicate the components of the monolithic overall structure form an indivisible whole not reasonably capable of being separated.

Apparatuses, systems, device structures, and techniques are described herein related to ferroelectric material stacks deploying a hafnium oxide-based ferroelectric material and a defect compensation material on the hafnium oxide-based ferroelectric material for increased memory endurance and other device enhancements.

As discussed, hafnia-based ferroelectric/antiferroelectric material systems (e.g., ferroelectric oxides) have promising characteristics for deployment in memory devices. These material systems also have promising characteristics for deployment in other devices including ferroelectric field effect transistors (FeFETs), ferroelectric tunnel junctions (FTJs), and others due to the non-volatile nature of the material systems. For example, the polarity of the material system, which can be switched, may be detected, and is maintained by the material system until it is again switched. As used herein, the term ferroelectric material or similar terms are inclusive of anti-ferroelectric material systems. In such ferroelectric material systems, endurance of the system is an ongoing concern. For example, the memory devices need to continue to function after >10¹³ read and write cycles for cache-level applications. However, oxygen vacancy defects generated in the devices during field cycling as well as those present when the devices are fabricated cause difficulties in meeting the required read and write cycle endurance. The defects during fabrication can be reduced by optimization of the deposition of the hafnia-based ferroelectric during, for example, atomic layer deposition (ALD). However, the field cycle defects are not resolved.

In some embodiments, a defect compensation material or layer is provided on the hafnia-based ferroelectric to reduce oxygen vacancies and/or eliminate their negative impacts on device performance during read and write cycling. The defect self-compensation effect provided by the defect compensation material or layer can significantly reduce domain pinning due to the generated oxygen vacancy defects. For example, domain pinning is the main reason for endurance problems in the hafnia-based ferroelectric devices, and domain pinning is due to oxygen vacancy defects in the hafnia-based ferroelectric material system. The discussed defect compensation material or layer resolves or mitigates these issues and can increase device endurance into >10¹³ read and write cycles and beyond.

As discussed herein, a defect compensation material or layer is provided at the interface of the hafnia-based ferroelectric material. The materials of the defect compensation material or layer are chosen to mitigate defect generation and/or mitigate the impacts of defect generation during field cycling for hafnia-based ferroelectrics for highly reliable ferroelectric capacitors (e.g., inclusive of ferroelectric and anti-ferroelectric material systems for capacitors and other devices). In some embodiments, the defect compensation material or layer has a stronger oxygen bound dissociation energy compared to that of the hafnia-based ferroelectric material and the defect compensation material or layer may be a non-stoichiometric compound. In some embodiments, when oxygen defects are formed in the hafnia-based ferroelectric material, they are compensated for by the defect compensation material or layer form improved device performance.

While not being bound by theory, oxygen defects formed in the hafnia-based ferroelectric material may release an oxygen atom that provides an oxygen vacancy defect in the hafnia-based ferroelectric material. The oxygen atom may then be captured by the defect compensation material or layer having the greater oxygen bound dissociation energy. Notably, the oxygen atom is also securely bound by the defect compensation material or layer and the capture may be enhanced by the non-stoichiometry of the defect compensation material or layer. When the oxygen atom is not captured, it is lost by the hafnia-based ferroelectric material with a net change in charge (i.e., 2+ at the vacancy) in the material, and absent defect compensation, the change in net charge interacts with the polarization effect of the device, causing it to become difficult to switch and reducing endurance. By capturing the oxygen atom (i.e., 2−) in the defect compensation material or layer, the net charge of the material stack is not changed, which advantageously increases endurance of the device. The defect compensation material or layer may be any suitable material such as an oxide of boron, thorium, tantalum, or carbon as discussed further herein.

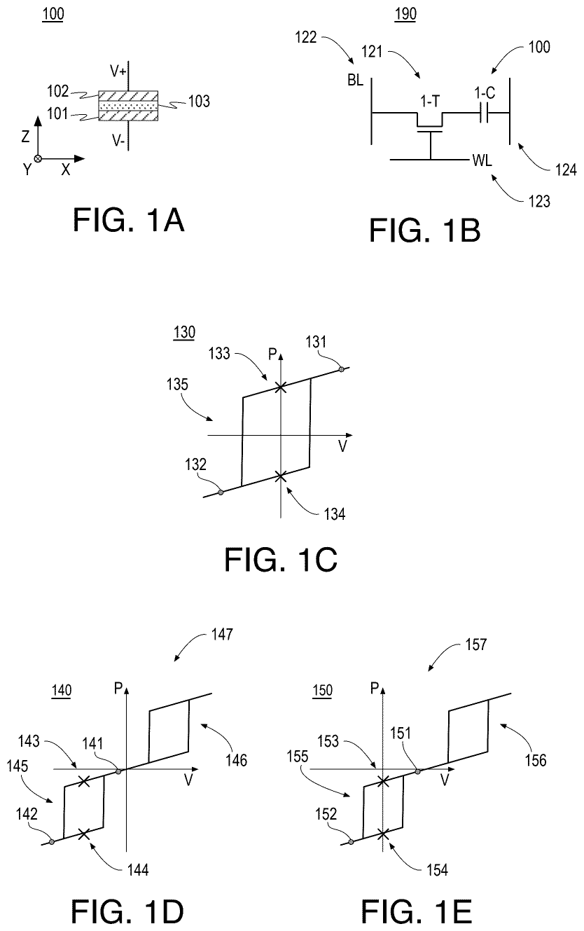

FIG. 1A illustrates a schematic of an example ferroelectric capacitor 100, arranged in accordance with at least some implementations of the present disclosure. As shown in FIG. 1A, ferroelectric (FE) capacitor 100 includes a multi-layer FE material stack 103 between electrodes 101, 102. As discussed in detail herein, multi-layer FE material stack 103 may be a multilayer stack including a ferroelectric hafnium oxide-based material layer, and a defect compensation material or layer on one or both sides of the ferroelectric hafnium oxide-based material layer. For example, the defect compensation material or layer may be between the ferroelectric hafnium oxide-based material layer and electrode 101, between the ferroelectric hafnium oxide-based material layer and electrode 102, or both. In any event, the defect compensation material(s) or layer(s) are directly on the ferroelectric hafnium oxide-based material layer of FE capacitor 100.

Electrodes 101, 102 may be on a defect compensation material or layer, on the ferroelectric hafnium oxide-based material layer, or on an intervening layer, depending on the materials deployed in multi-layer FE material stack 103, as discussed further herein below. For example, a seed layer may be formed on a bottom electrode to promote growth of an orthorhombic phase of the ferroelectric hafnium oxide-based material layer. In some embodiments, electrode 101 is or includes a titanium nitride layer on which the seed layer may be formed. However, electrode 101 and electrode 102 may be any suitable material such as tantalum nitride, niobium nitride, ruthenium, tungsten, molybdenum, or combinations of such materials. The multi-layer nature of multi-layer FE material stack 103 is not illustrated in FIG. 1A for the sake of clarity of presentation. Although illustrated with respect to deployment in FE capacitor 100, multi-layer FE material stack 103 may be deployed in any suitable device context.

FIG. 1B illustrates a diagram of an example memory cell circuit 190, arranged in accordance with at least some implementations of the present disclosure. As shown in FIG. 1B, FE capacitor 100 may be deployed in memory cell circuit 190, which provides a one transistor-one FE capacitor (1T-1F) architecture. Such 1T-1F architectures may be deployed in a variety of contexts including capacitor over bit line (COB) architectures (e.g., deep trench architectures), 3D array memory device architectures (e.g., vertically stacked capacitor architectures), or others. As shown, memory cell circuit 190 includes FE capacitor 100 and a transistor 121. Transistor 121 may have any suitable architecture. For example, transistor 121 may be a planar field effect transistor (FET), a FinFET, a gate all around (GAA) transistor (GAA-FET), or other. The gate of transistor 121 is controlled via a word line 123 and the source/drain of transistor 121 are coupled to FE capacitor 100 and a bit line 122. FE capacitor 100 is further coupled to a plate-line 124.

FIG. 1C illustrates a plot 130 showing polarization versus voltage for a capacitor deploying a ferroelectric material, arranged in accordance with at least some implementations of the present disclosure. Unlike a typical dielectric based capacitor, a ferroelectric capacitor uses polarization charge to store the memory states, where a positive polarization charge state 133 indicates, for example, a stored bit of “1” and a negative polarization charge state 134, indicate, for example, a stored bit of “0”. Plot 130 illustrates the hysteresis property of a ferroelectric material-based device. A ferroelectric material exhibits ferroelectricity, which is a property by which a spontaneous electric polarization can be revered by an electric field (e.g., applied voltage). For example, when a dielectric material is polarized, the induced polarization is proportional to the applied external electric field. Ferroelectric materials, on the other hand, demonstrate a spontaneous non-zero polarization even when the applied electric field is zero. As such, the spontaneous polarization may be reversed by an applied electric field in the opposite direction. This results in a hysteresis loop 135 because the polarization of a ferroelectric material is dependent not only on the present electric field but also on its history. Hysteresis loop 135 of plot 130 shows two stable operating positions or states for a ferroelectric capacitor, as discussed above: positive polarization charge state 133 and negative polarization charge state 134. These stable charge states 133, 134 indicate that the direction of polarization can be switched from one to another by application, for example, of positive switching voltage 131 and negative switching voltage 132.

FIG. 1D illustrates a plot 140 showing polarization versus voltage for a capacitor deploying an anti-ferroelectric material, arranged in accordance with at least some implementations of the present disclosure. As shown in FIG. 1D, in contrast to a ferroelectric material, for an anti-ferroelectric (AFE) material, an AFE capacitor behavior having a double hysteresis loop 147 is observed due to the AFE material having an ordered array of electric dipoles but oriented in opposite (antiparallel) directions (in contrast to ferroelectric materials having spontaneous electric polarization due to changes in strengths of the dipoles). As used herein, the terms AFE and AFE materials indicate a material (at the bulk level, which may include multiple materials or material layers) having such material properties. The AFE characteristic may be realized in HZO by increasing zirconium concentration.

Double hysteresis loop 147 includes a first hysteresis loop 145 and a second hysteresis loop 146. First hysteresis loop 145 (as illustrated here) or second hysteresis loop 146 may be utilized or harvested for operation of AFE capacitor 100 while the other loop is not used (e.g., its characteristics are not of interest in the operation of AFE capacitor 100. Similar to hysteresis loop 135, first hysteresis loop 145 has stable polarization charge states 143, 144, that may be used to indicate stored bits. These stable states 143, 144 indicate that the direction of polarization can be switched from one to another by application, for example, of switching voltage 141 and switching voltage 142.

FIG. 1E illustrates a plot 150 showing polarization versus voltage for a capacitor deploying an anti-ferroelectric material after voltage shift, arranged in accordance with at least some implementations of the present disclosure. As shown in FIG. 1E, in contrast to double hysteresis loop 147, double hysteresis loop 157 is shifted such that stable polarization charge states 153, 154 are at 0V to enable improved device operation. Such shifting may be provided using any suitable technique or techniques such as selection of different metal materials for electrodes 101, 102, as is known in the art. Double hysteresis loop 157 includes first and second hysteresis loops, 155, 156, with first hysteresis loop 155 used for operation of AFE capacitor 100. Notably, switching voltages 151, 152, and the difference between them, are reduced with respect to those discussed with respect to ferroelectric capacitors (refer to FIG. 1C), which greatly reduces breakdown in AFE capacitors 100. For example, AFE capacitors 100 may be operated at lower voltages for improved reliability and endurance.

As discussed, in some contexts, memory devices may deploy a ferroelectric material system, inclusive of anti-ferroelectric material systems. However, the ferroelectric material systems discussed herein may be deployed in any suitable context such as ferroelectric field effect transistors (FeFETs), ferroelectric tunnel junctions (FTJs), and others.

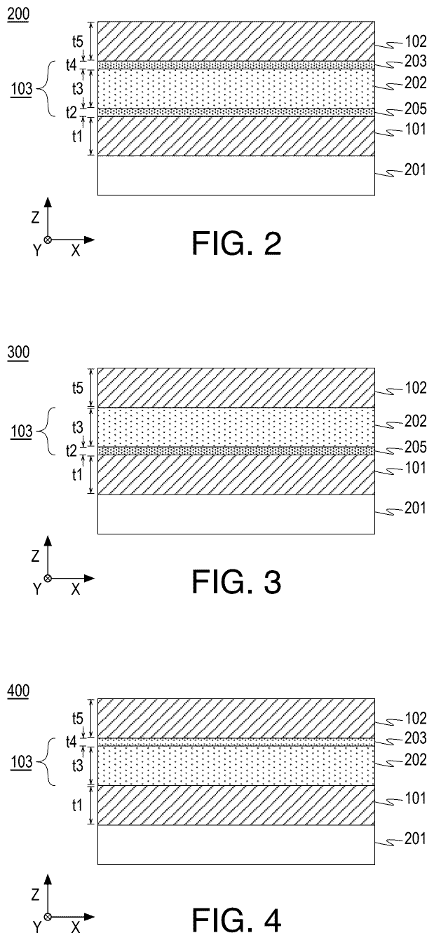

FIG. 2 illustrates a cross-sectional side view of an example ferroelectric device structure 200 having a defect compensation layer on each side of a ferroelectric hafnium oxide-based material layer, arranged in accordance with at least some implementations of the present disclosure. As shown in FIG. 2, ferroelectric (FE) device structure 200 includes a substrate 201, bottom electrode 101, a defect compensation layer 205, an FE hafnium oxide-based material layer 202, a defect compensation layer 203, and top electrode 102. Bottom electrode 101, defect compensation layer 205, FE hafnium oxide-based material layer 202, defect compensation layer 203, and top electrode 102 may be formed using any suitable technique or techniques such as those discussed herein below.

In some embodiments, substrate 201 is a material used to manufacture integrated circuits inclusive of semiconductor materials such as, but not limited to, single crystal silicon, polycrystalline silicon and silicon on insulator (SOI). In some embodiments, substrate 201 includes other semiconductor materials such as germanium, silicon germanium, or a suitable group III-V or group III-N compound. Substrate 201 may also include semiconductor materials, metals, dopants, and other materials commonly found in semiconductor substrates. In some embodiments, substrate 201 includes a device layer (e.g., transistor devices), metallization stack(s), or other device layers.

Bottom electrode 101 may include any suitable conductive material such as a metal. In some embodiments, bottom electrode 101 is or includes a layer of titanium nitride (TiN, e.g., titanium and nitrogen). In some embodiments, bottom electrode 101 is or includes tungsten (W), tantalum nitride (TaN, e.g., tantalum and nitrogen), niobium nitride (NbN, e.g., niobium and nitrogen), ruthenium (Ru), ruthenium oxide (RuOx) iridium (Ir), aluminum (Al), palladium (Pd), tin (Sn), copper (Cu), titanium (Ti), cobalt (Co), chromium (Cr), molybdenum (Mo), molybdenum nitride (MoN), lanthanum (La), nickel (Ni), gold (Au), platinum (Pt), scandium (Sc), or combinations of these materials. For anti-ferroelectric materials, different metal electrodes may be needed to provide a shift in a double hysteresis loop due to work function difference as is known in the art.

As shown, in some embodiments, FE device structure 200 includes defect compensation layer 205 on electrode 101. In other embodiments, as discussed below, FE hafnium oxide-based material layer 202 or a seed layer is on electrode 101. In some embodiments, FE device structure 200 includes defect compensation layer 203 on FE hafnium oxide-based material layer 202. Defect compensation layer 203 and defect compensation layer 205 are discussed further herein below.

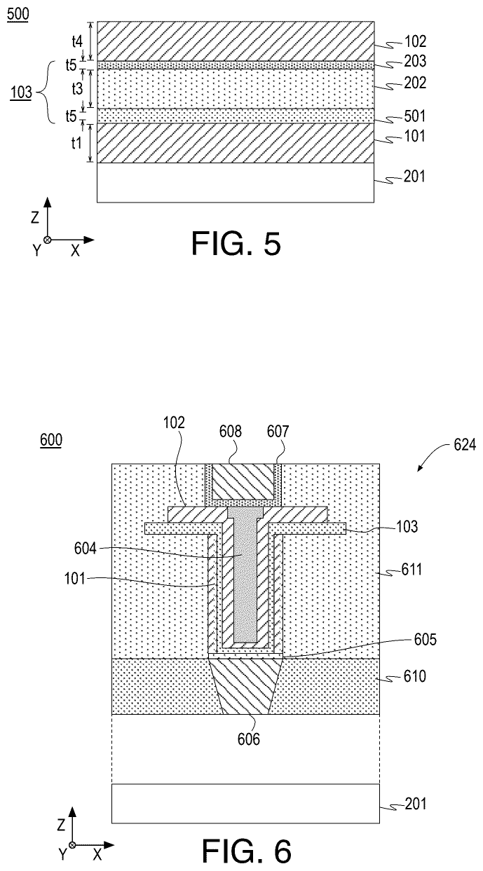

FE hafnium oxide-based material layer 202 is between electrode 101 and electrode 102. In various embodiments, FE hafnium oxide-based material layer 202 is on defect compensation layer 205 (as shown in FIGS. 2 and 3), FE hafnium oxide-based material layer 202 is on electrode 101 (as shown in FIG. 4), or FE hafnium oxide-based material layer 202 is on a seed layer (as shown in FIG. 5). In any event, FE hafnium oxide-based material layer 202 is between electrode 101 and electrode 102 and FE hafnium oxide-based material layer 202 is a part of a multi-layer FE material stack 103 that may be deployed in any capacitor, capacitor structure, or device discussed herein.

In some embodiments, multi-layer FE material stack 103 includes defect compensation layer 205, FE hafnium oxide-based material layer 202 on defect compensation layer 205, and defect compensation layer 203 on FE hafnium oxide-based material layer 202 (as shown in FIG. 2). In some embodiments, multi-layer FE material stack 103 includes defect compensation layer 205 and FE hafnium oxide-based material layer 202 on defect compensation layer 205 with electrode 102 (or other layer) on FE hafnium oxide-based material layer 202 (as shown in FIG. 3). In some embodiments, multi-layer FE material stack 103 includes FE hafnium oxide-based material layer 202 and defect compensation layer 203 on FE hafnium oxide-based material layer 202, with multi-layer FE material stack 103 being on electrode 101 (as shown in FIG. 4). In some embodiments, multi-layer FE material stack 103 includes a seed layer on electrode 101, FE hafnium oxide-based material layer 202 on the seed layer, and defect compensation layer 203 on FE hafnium oxide-based material layer 202 (as shown in FIG. 5). In any case, at least one of defect compensation layer 203 and defect compensation layer 205 is directly on FE hafnium oxide-based material layer 202 to provide defect self-compensation effects as discussed herein.

As discussed, FE hafnium oxide-based material layer 202 is a ferroelectric material. FE hafnium oxide-based material layer 202 includes hafnium and oxygen and may further include one or more dopants. For example, FE hafnium oxide-based material layer 202 may be doped hafnium oxide. In some embodiments, FE hafnium oxide-based material layer 202 includes hafnium and oxygen, and one or more dopants including one or more of zirconium (Zr), silicon (Si), lanthanum (La), aluminum (Al), niobium (Nb), germanium (Ge), or scandium (Sc). In some embodiments, FE hafnium oxide-based material layer 202 includes hafnium, zirconium, and oxygen. For example, FE hafnium oxide-based material layer 202 may be hafnium zirconium oxide (HZO). In some embodiments, oxygen FE hafnium oxide-based material layer 202 includes hafnium, zirconium, oxygen, and one or more additional dopants. In some embodiments, the additional dopant is one of silicon, aluminum, or lanthanum. In some embodiments, the additional dopant is lanthanum. In some embodiments, the additional dopant is one or more of silicon, lanthanum, aluminum, niobium, germanium, or scandium.

In the embodiment of FIG. 2, defect compensation layer 203 and defect compensation layer 205 are on opposite sides of FE hafnium oxide-based material layer 202. Defect compensation layer 203 and defect compensation layer 205 may be the same materials and may have the same characteristics or they may be different. In any case, defect compensation layer 203 and defect compensation layer 205 provide defect self-compensation effects for FE hafnium oxide-based material layer 202. Defect compensation layer 203 and defect compensation layer 205 may be any suitable materials that provide such defect self-compensation effects for FE hafnium oxide-based material layer 202.

In some embodiments, defect compensation layer 205 and/or defect compensation layer 203 is a metal oxide having a greater oxygen bound dissociation energy than that of hafnium oxide (Hf—O), zirconium oxide (Zr—O), or both. For example, HZO materials for FE hafnium oxide-based material layer 202 are particularly advantageous in capacitor structures due to manufacturability, performance, and other concerns. However, HZO materials have relatively high oxygen bound dissociation energy. For example, oxygen bound dissociation energy is indicative of how strong the bonds are in a particular material to form a bound with oxygen and may be a measure of how much energy is needed to break such bonds. The oxygen bound dissociation energy for a particular material may be the bound dissociation energy for the main hetero-bond in the material, an average of hetero-bonds if there are more than one type, or the like. Hafnium has an oxygen bound dissociation energy between hafnium and oxygen (Hf—O) of about 791 kJ/mol and zirconium has an oxygen bound dissociation energy between zirconium and oxygen (Zr—O) of about 760 kJ/mol. In some embodiments, defect compensation layer 205 has an oxygen bound dissociation energy greater than that of both hafnium and zirconium such as an oxygen bound dissociation energy of greater than 791 kJ/mol.

As discussed, defect compensation layer 205 and/or defect compensation layer 203 has a greater oxygen bound dissociation energy than of hafnium and zirconium. Notably, there are not many elements that are able to provide the desired self-compensation effect due to the relatively high oxygen bound dissociation energies of hafnium and zirconium. In some embodiments, defect compensation layer 205 and/or defect compensation layer 203 is an oxide of one of born, thorium, tantalum, or carbon, which have a greater bound dissociation energy than of hafnium oxide and zirconium oxide.

In some embodiments, defect compensation layer 205 and/or defect compensation layer 203 is or includes boron oxide (e.g., boron and oxygen). In some embodiments, defect compensation layer 205 and/or defect compensation layer 203 is or includes thorium oxide (e.g., thorium and oxygen). In some embodiments, defect compensation layer 205 and/or defect compensation layer 203 is or includes tantalum oxide (e.g., tantalum and oxygen). In some embodiments, defect compensation layer 205 and/or defect compensation layer 203 is or includes an oxide of carbon (e.g., carbon and oxygen). For example, boron and oxygen (e.g., B—O) has a bound dissociation energy of about 806 kJ/mol, thorium and oxygen (e.g., Th—O) has a bound dissociation energy of about 854 kJ/mol, tantalum and oxygen (e.g., Ta—O) has a bound dissociation energy of about 805 kJ/mol, and carbon and oxygen (e.g., C—O) has a bound dissociation energy of about 1075 kJ/mol, all of which are higher that the bound dissociation energy of hafnium and oxygen (Hf—O) and zirconium and oxygen (Zr—O). In some embodiments, defect compensation layer 205 and/or defect compensation layer 203 is a combination of two or more such materials. For example, carbon-oxygen bonds may be incorporated in a film or material layer including another stabilizing element.

In some embodiments, defect compensation layer 205 and/or defect compensation layer 203 is non-stoichiometric such that it is capable or more capable of passivating the defects generated by FE hafnium oxide-based material layer 202. In some embodiments, oxygen defects formed in FE hafnium oxide-based material layer 202 release an oxygen atom that provides an oxygen vacancy defect in FE hafnium oxide-based material layer 202 while the released oxygen atom is captured by defect compensation layer 205 and/or defect compensation layer 203, which has the greater bound dissociation energy. The non-stoichiometric nature of defect compensation layer 205 and/or defect compensation layer 203 allows room for capture of the oxygen atom. The greater bound dissociation energy increases the likelihood of capture and securely bonds the oxygen atom. When the oxygen atom is captured, multi-layer FE material stack 103 maintains its net charge as the loss of the oxygen atom from FE hafnium oxide-based material layer 202 gives 2+ charge while the capture of the oxygen atom in defect compensation layer 205 and/or defect compensation layer 203 gives 2− charge, with those changes balancing out across multi-layer FE material stack 103. Notably, with a net change of zero, there is substantially no impact to the polarization characteristics during switching and the endurance of the device deploying multi-layer FE material stack 103 is improved. For example, by capturing the oxygen atom(s), the device is more neutral in the local area and polarization switching is not affected. Thereby, the endurance of the device is improved relative to a device absent defect compensation layer 205 and/or defect compensation layer 203.

As discussed, in some embodiments, defect compensation layer 205 and/or defect compensation layer 203 is a non-stoichiometric compound. In some embodiments, defect compensation layer 205 and/or defect compensation layer 203 is a non-stoichiometric compound having an oxygen deficiency relative to the other element (i.e., boron, thorium, tantalum, or carbon). As used herein, the term deficiency with respect to an element of a non-stoichiometric compound indicates the element has less than the amount of the element as defined by an elemental composition of the material represented by a ratio of well-defined natural numbers, such that the deficiency defines the non-stoichiometry of the compound. For example, nonstoichiometric compounds are compounds deviated from stoichiometry, and the deficient element has less than required for stoichiometry.

In some embodiments, defect compensation layer 205 and/or defect compensation layer 203 is or includes non-stoichiometric boron oxide (e.g., with stoichiometric boron oxide being 40% boron, 60% oxygen; B₂O₃). In some embodiments, defect compensation layer 205 and/or defect compensation layer 203 is or includes not less than 40 percent boron and not more than 40 percent oxygen. In some embodiments, defect compensation layer 205 and/or defect compensation layer 203 is or includes not less than 40 percent boron and not more than 50 percent oxygen. In some embodiments, defect compensation layer 205 and/or defect compensation layer 203 is or includes not less than 40 percent boron and not more than 55 percent oxygen. In some embodiments, defect compensation layer 205 and/or defect compensation layer 203 is or includes not less than 40 percent boron and not more than 59 percent oxygen.

In some embodiments, defect compensation layer 205 and/or defect compensation layer 203 is or includes non-stoichiometric thorium oxide (e.g., with stoichiometric thorium oxide being 33.3% thorium, 66.6% oxygen; ThO₂). In some embodiments, defect compensation layer 205 and/or defect compensation layer 203 is or includes not less than 33.3 percent thorium and not more than 45 percent oxygen. In some embodiments, defect compensation layer 205 and/or defect compensation layer 203 is or includes not less than 33.3 percent thorium and not more than 55 percent oxygen. In some embodiments, defect compensation layer 205 and/or defect compensation layer 203 is or includes not less than 33.3 percent thorium and not more than 61 percent oxygen. In some embodiments, defect compensation layer 205 and/or defect compensation layer 203 is or includes not less than 33.3 percent thorium and not more than 65 percent oxygen.

In some embodiments, defect compensation layer 205 and/or defect compensation layer 203 is or includes non-stoichiometric tantalum oxide (e.g., with stoichiometric tantalum oxide being 28.57% tantalum, 71.43% oxygen; B₂O₃). In some embodiments, defect compensation layer 205 and/or defect compensation layer 203 is or includes not less than 28 percent tantalum and not more than 50 percent oxygen. In some embodiments, defect compensation layer 205 and/or defect compensation layer 203 is or includes not less than 28 percent tantalum and not more than 60 percent oxygen. In some embodiments, defect compensation layer 205 and/or defect compensation layer 203 is or includes not less than 28 percent tantalum and not more than 65 percent oxygen. In some embodiments, defect compensation layer 205 and/or defect compensation layer 203 is or includes not less than 28 percent tantalum and not more than 70 percent oxygen.

It is noted that boron and tantalum offer the advantage of relative ease of manufacture. In some embodiments, one of defect compensation layer 205 and defect compensation layer 203 includes oxygen and boron. In some embodiments, one of defect compensation layer 205 and defect compensation layer 203 includes oxygen and tantalum. In some embodiments, one of defect compensation layer 205 and defect compensation layer 203 includes oxygen and tantalum and the other of defect compensation layer 205 and defect compensation layer 203 includes oxygen and boron. In some embodiments, both of defect compensation layer 205 and defect compensation layer 203 includes oxygen and boron. In some embodiments, both of defect compensation layer 205 and defect compensation layer 203 includes oxygen and tantalum.

As shown, top electrode 102 may be on or over multi-layer FE material stack 103. Top electrode 102 may include any suitable conductive material such as a metal. In some embodiments, top electrode 102 is or includes a layer of titanium nitride (TiN, e.g., titanium and nitrogen). In some embodiments, top electrode 102 is or includes tungsten (W), tantalum nitride (TaN, e.g., tantalum and nitrogen), niobium nitride (NbN, e.g., niobium and nitrogen), ruthenium (Ru), iridium (Ir), aluminum (Al), copper (Cu), titanium (Ti), cobalt (Co), chromium (Cr), molybdenum (Mo), nickel (Ni), gold (Au), platinum (Pt), or combinations of these materials. In some embodiments, bottom electrode and/or top electrode 102 is or includes titanium and nitrogen, tantalum and nitrogen, niobium and nitrogen, ruthenium, tungsten, or molybdenum

As shown, bottom electrode 101, defect compensation layer 205, FE hafnium oxide-based material layer 202, defect compensation layer 203, and top electrode 101 may have thicknesses t1, t2, t3, t4, and t5, respectively. Such thicknesses, t2, t3, t4, and t5 may be any suitable thicknesses. In some embodiments, thickness t1 of bottom electrode 101 is in the range of 5 to 20 nm. In some embodiments, thickness t1 of bottom electrode 101 is in the range of 5 to 15 nm. In some embodiments, thickness t1 of bottom electrode 101 is about 10 nm. In some embodiments, thickness t1 of bottom electrode 101 is not more than 10 nm. In some embodiments, thickness t2 of defect compensation layer 205 is in the range of 0.5 to 5 nm. In some embodiments, thickness t2 of defect compensation layer 205 is in the range of 1 to 2 nm. In some embodiments, thickness t2 of defect compensation layer 205 is about 1 nm. In some embodiments, thickness t2 of defect compensation layer 205 is not more than 2 nm. In some embodiments, thickness t3 of FE hafnium oxide-based material layer 202 is in the range of 2 to 15 nm. In some embodiments, thickness t3 of FE hafnium oxide-based material layer 202 is in the range of 3 to 10 nm. In some embodiments, thickness t3 of FE hafnium oxide-based material layer 202 is not more than 10 nm. In some embodiments, thickness t4 of defect compensation layer 203 is in the range of 0.5 to 5 nm. In some embodiments, thickness t4 of defect compensation layer 203 is in the range of 1 to 2 nm. In some embodiments, thickness t4 of defect compensation layer 203 is about 1 nm. In some embodiments, thickness t4 of defect compensation layer 203 is not more than 2 nm. In some embodiments, thickness t5 of top electrode 102 is in the range of 5 to 20 nm. In some embodiments, thickness t5 of top electrode 102 is in the range of 5 to 15 nm. In some embodiments, thickness t5 of top electrode 102 is about 10 nm. In some embodiments, thickness t5 of top electrode 102 is not more than 10 nm.

As discussed, in some embodiments, defect compensation layer 205 and defect compensation layer 203 are on each side of FE hafnium oxide-based material layer 202. In other embodiments only one of defect compensation layer 205 and defect compensation layer 203 are deployed.

FIG. 3 illustrates a cross-sectional side view of an example ferroelectric device structure 300 having defect compensation layer 205 between ferroelectric hafnium oxide-based material layer 202 and bottom electrode 101, arranged in accordance with at least some implementations of the present disclosure. As shown in FIG. 3, ferroelectric (FE) device structure 300 includes substrate 201, bottom electrode 101, defect compensation layer 205, FE hafnium oxide-based material layer 202, and top electrode 102. Substrate 201, bottom electrode 101, defect compensation layer 205, FE hafnium oxide-based material layer 202, and top electrode 102 may have any characteristics discussed elsewhere herein.

In the embodiment of FIG. 3, FE hafnium oxide-based material layer 202 is between electrode 101 and electrode 102 such that FE hafnium oxide-based material layer 202 is on defect compensation layer 205 and defect compensation layer 205 is on electrode 101. Furthermore, electrode 102 is on FE hafnium oxide-based material layer 202. Notably, defect compensation layer 205 is on a bottom side or surface of FE hafnium oxide-based material layer 202 but a defect compensation layer is absent a top side or surface FE hafnium oxide-based material layer 202.

In some embodiments, defect compensation layer 205 may be on a seed layer or other intervening layer, which is on bottom electrode 101. Similarly, a capping layer or other intervening layer may be between top electrode 102 and FE hafnium oxide-based material layer 202. For example, a seed layer such as the seed layer discussed with respect to FIG. 5 may promote the formation of desired crystalline phases of the upper layers.

FIG. 4 illustrates a cross-sectional side view of an example ferroelectric device structure 400 having defect compensation layer 203 between ferroelectric hafnium oxide-based material layer 202 and top electrode 102, arranged in accordance with at least some implementations of the present disclosure. As shown in FIG. 4, ferroelectric (FE) device structure 400 includes substrate 201, bottom electrode 101, FE hafnium oxide-based material layer 202, defect compensation layer 203, and top electrode 102. Substrate 201, bottom electrode 101, FE hafnium oxide-based material layer 202, defect compensation layer 203, and top electrode 102 may have any characteristics discussed elsewhere herein.

In the embodiment of FIG. 4, FE hafnium oxide-based material layer 202 is between electrode 101 and electrode 102 such that FE hafnium oxide-based material layer 202 is on electrode 101 and defect compensation layer 203 is on FE hafnium oxide-based material layer 202. Furthermore, electrode 102 is on defect compensation layer 203. Notably, defect compensation layer 203 is on a top side or surface of FE hafnium oxide-based material layer 202 but a defect compensation layer is absent a bottom side or surface FE hafnium oxide-based material layer 202.

In some embodiments, FE hafnium oxide-based material layer 202 is advantageously on and grown from electrode 101 such that the formation of the orthorhombic phase of FE hafnium oxide-based material layer 202 is promoted as well as the formation of a pristine crystal. For example, due to the non-stoichiometric nature of defect compensation layer 205, the crystallization of FE hafnium oxide-based material layer 202 (e.g., HZO) can be compromised as defect compensation layer 205 does not provide a good template layer for crystallization.

In some embodiments, FE hafnium oxide-based material layer 202 may be on a seed layer or other intervening layer, which is on bottom electrode 101, as discussed with respect to FIG. 5. In some embodiments, a capping layer or other intervening layer may be between top electrode 102 and defect compensation layer 203.

FIG. 5 illustrates a cross-sectional side view of an example ferroelectric device structure 500 having defect compensation layer 203 between ferroelectric hafnium oxide-based material layer 202 and top electrode 102 and ferroelectric hafnium oxide-based material layer 202 on a seed layer 501, arranged in accordance with at least some implementations of the present disclosure. As shown in FIG. 5, ferroelectric (FE) device structure 500 includes substrate 201, bottom electrode 101, a seed layer 501, FE hafnium oxide-based material layer 202 on seed layer 501, defect compensation layer 203, and top electrode 102. Substrate 201, bottom electrode 101, FE hafnium oxide-based material layer 202, defect compensation layer 203, and top electrode 102 may have any characteristics discussed elsewhere herein.

In the embodiment of FIG. 5, FE hafnium oxide-based material layer 202 is between electrode 101 and electrode 102 such that FE hafnium oxide-based material layer 202 is on seed layer 501 and electrode 102 is on defect compensation layer 203. Defect compensation layer 203 is on a top side or surface of FE hafnium oxide-based material layer 202 but a defect compensation layer is absent a bottom side or surface FE hafnium oxide-based material layer 202.

In some embodiments, seed layer 501 is or includes titanium oxide (TiO₂, e.g., titanium and oxygen). In some embodiments, seed layer 501 is or includes one of aluminum oxide (Al₂O₃, e.g., aluminum and oxygen), vanadium oxide (V₂O₃, e.g., vanadium and oxygen), tantalum oxide (Ta₂O₅, e.g., tantalum and oxygen), zirconium oxide (ZrO₂, e.g., zirconium and oxygen), silicon oxide (SiO₂, e.g., silicon and oxygen), or molybdenum oxide (MoO₃, e.g., molybdenum and oxygen). For example, seed layer 501 may promote the formation of the orthorhombic phase of FE hafnium oxide-based material layer 202 relative to the tetragonal and monoclinic phases, with only the orthorhombic phase having the desired FE properties. Although characterized as a seed layer, seed layer 501 may be characterized simply as a material layer, material, layer, or the like.

Although illustrated in FIGS. 2 to 5 as planar capacitor structures, multi-layer FE material stack 103 may be deployed in any capacitor structure or other device such as FE field effect transistors (FeFETs), ferroelectric tunnel junctions (FTJs), and others. Any multi-layer FE material stack 103 discussed herein may be deployed in such device structures.

FIG. 6 illustrates a cross-sectional side view of an exemplary deep trench capacitor 600 having a defect compensation layer on at least one side of a ferroelectric hafnium oxide-based material layer, arranged in accordance with some embodiments of the disclosure. As shown, deep trench capacitor 600 and/or other components discussed herein may be deployed as part of an IC die 624, which is coupled to other components such as a power supply as is known in the art and as illustrated and discussed with respect to FIG. 11. In the example of FIG. 6, deep trench capacitor 600 may be deployed over a bit line (i.e., capacitor over bit line, COB). Deep trench capacitor 600 may have a U-shape (as shown) or a V-shape. As shown, deep trench capacitor 600 includes electrode 101, electrode 102, multi-layer FE material stack 103 (illustrated as a single component for the sake of clarity), a metal via 604, a barrier layer 605, an interconnect 606, a barrier layer 607, and an interconnect 608. Electrode 101 is coupled to interconnect 606 via barrier layer 605 and electrode 102 is coupled to interconnect 608 via metal via 604 and barrier layer 607. Deep trench capacitor 600 is formed in insulator 611 (e.g., silicon oxide, SiO₂), interconnect 606 is embedded in insulator 610, and such components are formed over substrate 201. Such components may include any characteristics discussed herein.

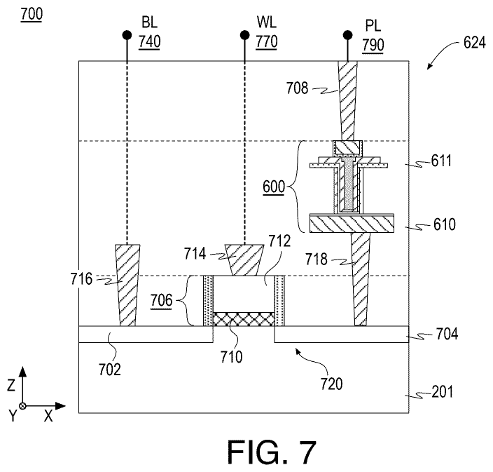

FIG. 7 illustrates a cross-section of an embedded dynamic random-access memory 700 including capacitor 600, arranged in accordance with some embodiments of the disclosure. Although illustrated with respect to deep trench capacitor 600 being deployed in embedded dynamic random-access memory 700, any capacitor or device structure discussed herein may be used. As shown, embedded dynamic random-access memory 700 includes a select transistor 720 coupled to a capacitor such as deep trench capacitor 600. Transistor 720 includes a source region 702, a drain region 704, and a gate 706. Transistor 720 further includes a gate contact 714 on and electrically coupled to gate 706, a source contact 716 on and electrically coupled to source region 702, and a drain contact 718 on and electrically coupled to drain region 704. In some embodiments, capacitor 600 is above transistor 720 such that electrode 101 is coupled to drain contact 718 and electrode 102 is coupled to a via 708. However, other architectures may be used.

In some embodiments, transistor 720 is a metal-oxide-semiconductor field-effect transistor (MOSFET or simply MOS transistors). Transistor 720 may be a planar transistor (as shown) or a nonplanar transistor such as a FinFET or a gate all around transistor such as a nanoribbon or nanowire transistor. Data is written into capacitor 600 as charge via a bit line (BL) 740 when access transistor 720 is turned on by applying a voltage on a word line WL 770. Interconnect 608 couples to a plate-line 790 through a metal via 708. In some embodiments, gate 706 is formed of at least two layers, gate dielectric layer 710 and gate electrode layer 712. Gate dielectric layer 710 may include one layer or a stack of layers including one or more of silicon dioxide and/or a high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Gate electrode layer 712 is on gate dielectric layer 710 and may be at least one a P-type work-function metal (e.g., ruthenium, palladium, platinum, cobalt, nickel, and conductive metal oxides, e.g., ruthenium oxide) or a N-type work-function metal (e.g., hafnium, zirconium, titanium, tantalum, aluminum, alloys of these metals, and carbides of these metals such as hafnium carbide, zirconium carbide, titanium carbide, tantalum carbide, and aluminum carbide), depending on whether the transistor is to be a PMOS or an NMOS transistor. In some embodiments, the gate electrode layer 712 may comprise of a stack of two or more metal layers, where one or more metal layers are work-function metal layers and at least one metal layer is a conductive fill layer.

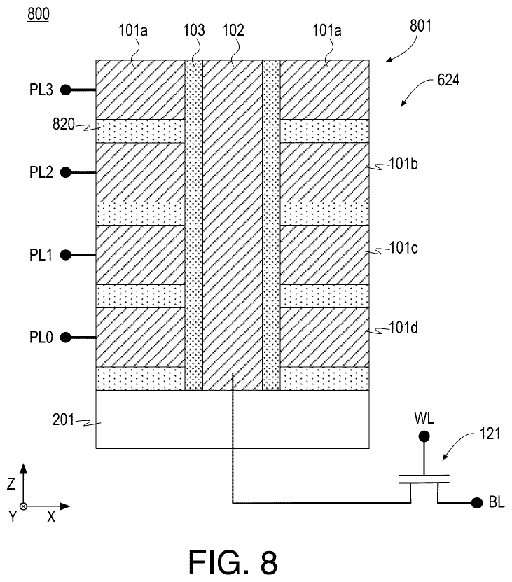

FIG. 8 illustrates a cross-sectional side view of a multiple capacitor stacked memory device 800 including capacitors having a defect compensation layer on at least one side of a ferroelectric hafnium oxide-based material layer, arranged in accordance with some embodiments of the disclosure. As shown in FIG. 8, memory device 800 includes multiple FE capacitors 801 having outer electrodes 101a-d, multi-layer FE material stack 103, and a shared electrode 102. Memory device 800 includes a vertically aligned array of FE capacitors 801 such that each FE capacitor 801 includes an electrode 101a-d, and a portion of electrode 102, which extends vertically through FE capacitors 801, electrodes 101a-d, and multi-layer FE material stack 103. Electrode 102 electrically connects to select transistor 121, as discussed herein. Insulators 820 surround electrode 102 and vertically separate and electrically isolate electrodes 101a-d.

Electrodes 101a-d may each be part of an integrated structure coupled to a corresponding plate line. For example, multi-layer FE material stack 103 may be on an inner surface of a corresponding plate line, which is integral with corresponding electrodes 101a-d. In the example of FIG. 8, multi-layer FE material stack 103 is on an inner surface of plate lines PL0, PL1, PL2, PL3, which are each integral with a corresponding electrodes 101a-d. Such components may include any characteristics discussed herein.

Transistor 121 controls access to the memory array by electrically connecting (or not) electrode 102 to a bit line BL connected at a drain contact of transistor 121. When transistor 121 conducts, electrode 102 on electrically connected to bit line BL. The conduction of transistor 121 is controlled by the voltage signal applied to a gate electrode by a word line WL. Since electrode 102 is shared for all FE capacitors 801 in the group, any bit stored in any of FE capacitors 801 is accessible by single transistor 121. With transistor 121 accessing the entire memory array of FE capacitors 801, individual control of FE capacitors 801 is by electrodes 101a-d using plate lines PL0-PL3 in concert with transistor 121.

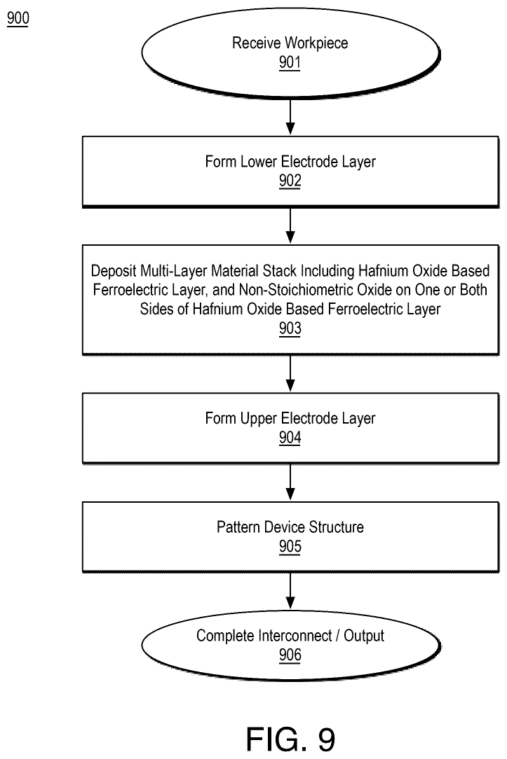

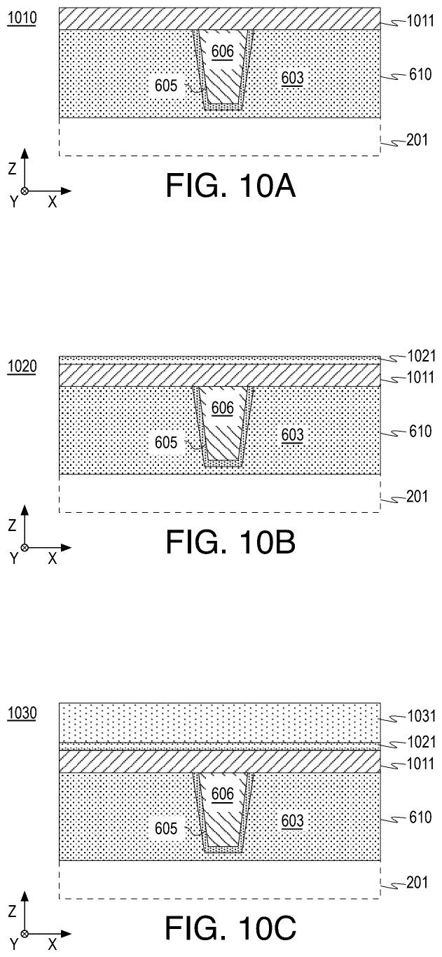

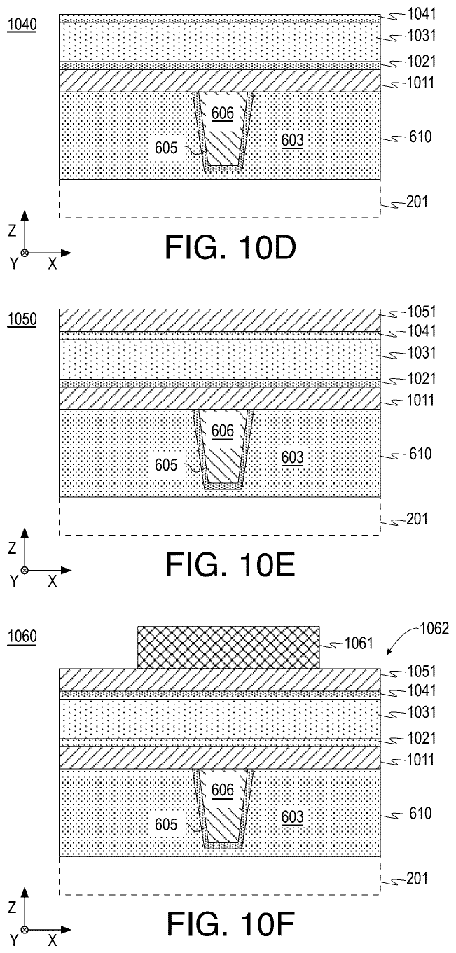

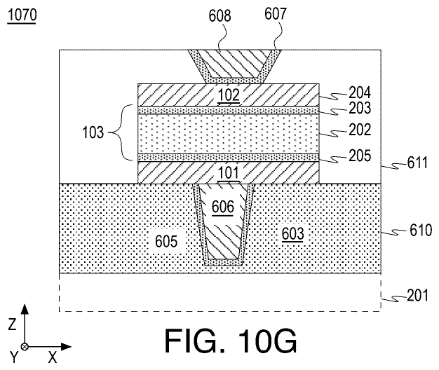

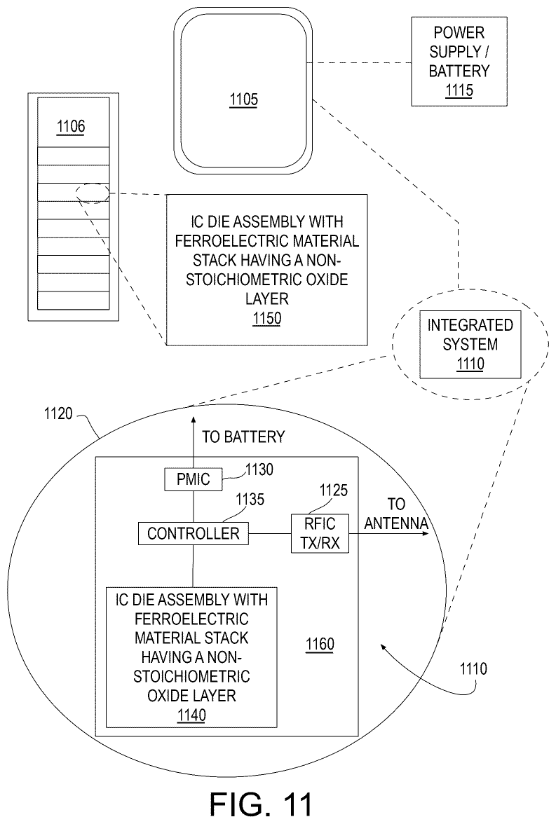

FIG. 9 is a flow diagram illustrating methods 900 for forming a device including a defect compensation layer on at least one side of a ferroelectric hafnium oxide-based material layer, arranged in accordance with some embodiments of the disclosure. Methods 900 may be practiced, for example, to fabricate any of FE devices discussed herein. Although illustrated with respect to fabricating an FE capacitor, methods 900 may be used to fabricate any device that includes an FE material stack such as an FeFET, an FTJ, or the like. FIGS. 10A, 10B, 10C, 10D, 10E, 10F, and 10G are cross-sectional views of a device structure evolving as methods 900 are practiced, arranged in accordance with some embodiments of the disclosure.

Methods 900 begin at input operation 901 where a workpiece including one or more material layers of a monolithic IC is received. In some embodiments, the workpiece is a large format (e.g., 300-450 mm) wafer and includes at least a device coupling or metallization layer on a working surface of the wafer. Processing continues at operation 902, where a lower electrode layer is formed using any suitable technique or techniques such as blanket deposition techniques including atomic layer deposition (ALD) processing. In the example illustrated in FIG. 10A, device structure 1010 includes an interconnect 606 over substrate 201, with interconnect 606 on a barrier layer 605. Interconnect 606 and barrier layer 605 are embedded within insulator 610. Insulator 610 may be silicon dioxide, silicon nitride, silicon carbide, or a low-k dielectric such as carbon doped silicon oxide. Barrier layer 605 may include tantalum, tantalum nitride, or ruthenium, for example. Interconnect 606 includes a fill metal that may be cobalt, copper, tungsten, or ruthenium, for example.

As shown in FIG. 10A, device structure 1010 also includes a lower electrode material layer 1011 (as formed at operation 902), which is to become electrode 101 of device structure 1070. Electrode material layer 1011 may include any material or materials as discussed herein with respect to electrodes 101, 102. In some embodiments, electrode material layer 1011 is titanium nitride (e.g., includes titanium and nitrogen). However, other materials discussed herein may be used. Electrode material layer 1011 may be formed using any suitable technique or techniques such as blanket deposition. The blanket deposition may be performed with an ALD process, for example.

Returning to FIG. 9, methods 900 continue at operation 903, where a multi-layer FE material stack is blanket deposited adjacent the lower electrode material layer. The multi-layer FE material stack may include a hafnium oxide-based FE material layer and a defect compensation layer (i.e., a non-stoichiometric oxide having a high bound dissociation energy) on one or both sides of the hafnium oxide-based FE material layer. For example, blanket material layers corresponding to the components of any multi-layer FE material stack 103 discussed herein may be blanket deposited at operation 903. Any deposition technique or techniques known to be suitable for deposition of the materials of a multi-layer FE material stack may be practiced at operation 903, but in some exemplary embodiments, one or more layers of the multi-layer FE material stack are deposited with an ALD process. In some embodiments, multiple adjacent layers of the multi-layer FE material stack (and/or the layers of the lower and upper electrode) are formed while the workpiece is in the same process chamber and without breaking vacuum of the process chamber. In some embodiments, forming the hafnium oxide-based FE material layer and forming one or both defect compensation layers includes atomic layer deposition of the hafnium oxide-based FE material layer and the defect compensation layer(s) within a continuously sealed process chamber.

FIG. 10B illustrates an example device structure 1020 similar to device structure 1010 after blanket deposition of a defect compensation material layer 1021. Defect compensation material layer 1021 may include any material or materials as discussed herein with respect to defect compensation layers 203, 205. In some embodiments, defect compensation material layer 1021 is or includes a non-stoichiometric oxide of one of boron, thorium, tantalum, or carbon. Defect compensation material layer 1021 may be formed using any suitable technique or techniques such as an ALD process, for example. In some embodiments, defect compensation material layer 1021 is not formed on lower electrode material layer 1011 in methods 900. Instead, a FE hafnium oxide-based material layer may be formed directly on lower electrode material layer 1011 or a seed layer may be formed on lower electrode material layer 1011 and the FE hafnium oxide-based material layer may be formed on the seed layer. In some embodiments, the seed layer is formed using ALD.

FIG. 10C illustrates an example device structure 1030 similar to device structure 1020 after blanket deposition of a FE hafnium oxide-based material layer 1031. FE hafnium oxide-based material layer 1031 may include any material or materials as discussed herein with respect to FE hafnium oxide-based material layer 202. In some embodiments, FE hafnium oxide-based material layer 1031 is HZO (e.g., includes hafnium, zirconium, and oxygen) or HZO doped with one or more additional elements such as silicon, lanthanum, aluminum, niobium, germanium, or scandium. FE hafnium oxide-based material layer 1031 may be formed using any suitable technique or techniques such as an ALD process, for example. In the illustrated example, FE hafnium oxide-based material layer 1031 is formed on defect compensation material layer 1021. In other embodiments, defect compensation material layer 1021 is formed on lower electrode material layer 1011 or a seed layer.

FIG. 10D illustrates an example device structure 1040 similar to device structure 1030 after blanket deposition of a defect compensation material layer 1041. Defect compensation material layer 1041 may include any material or materials as discussed herein with respect to defect compensation layers 203, 205 and defect compensation material layer 1041 may be formed using any suitable technique or techniques such as an ALD process. For example, defect compensation material layer 1041 may be a non-stoichiometric oxide of one of boron, thorium, tantalum, or carbon. In some embodiments, defect compensation material layer 1021 is not formed on FE hafnium oxide-based material layer 1031 in methods 900. Instead, an upper electrode material layer may be formed directly on FE hafnium oxide-based material layer 1031 or a capping layer may be formed on FE hafnium oxide-based material layer 1031 and the upper electrode material layer may be formed on the capping layer. In some embodiments, the capping layer is formed using ALD.

Returning to FIG. 9, processing continues at operation 904, where an upper electrode material layer is blanket deposited on the multi-layer FE material stack. Although any deposition technique or techniques known to be suitable for such deposition may be practiced at operation 904, in some exemplary embodiments, the upper electrode material layer is deposited with an ALD process.

FIG. 10E illustrates an example device structure 1050 similar to device structure 1040 after blanket deposition of an electrode material layer 1051 on defect compensation material layer 1041. Upper electrode material layer 1051 is to become electrode 102 of device structure 1070. Electrode material layer 1051 may include any material or materials as discussed herein with respect to electrodes 101, 102. In some embodiments, electrode material layer 1051 is titanium nitride (e.g., includes titanium and nitrogen). However, any materials discussed herein may be used. Electrode material layer 1051 may be formed using any suitable technique or techniques such as an ALD process, for example.

Returning to FIG. 9, methods 900 continue at operation 905, where the device material layers formed at operations 902-904 are patterned with any subtractive process(es) suitable for the various material layer compositions. Following device patterning, any remaining interconnect levels of the IC may be completed, and the resultant structure may be output at operation 906. For example, the upper electrode of the device may be connected to other circuit nodes with an upper-level metallization.

FIG. 10F illustrates an example device structure 1060 similar to device structure 1050 after patterning a mask 1061 on electrode material layer 1051. Mask 1061 defines a polygon area and position of a device for patterning material layer stack 1062, for example, relative to interconnect 606. Mask 1061 may be formed with any lithographic process(es) as embodiments are not limited in this respect. FIG. 10G illustrates an example device structure 1070 similar to device structure 1060 after the patterning of material layer stack 1062. In some embodiments, material layer stack 1062 may be patterned with one or more plasma etch processes. Such etch processing defines sidewalls into the various material layers 1011, 1021, 1031, 1041, 1051 to form electrode 101, multi-layer FE material stack 103, and electrode 102, respectively. FIG. 10G further illustrates an example where an upper-level interconnect 608 and barrier layer 607 has been fabricated in contact with electrode 102, with upper-level interconnect 608, barrier layer 607, electrode 101, multi-layer FE material stack 103, and electrode 102 buried in insulator 611. Barrier layer 607 may provide for improved adhesion and may include, for example, tantalum, tantalum nitride, or ruthenium in contact with electrode 102. Interconnect 608 may include any suitable fill metal such as cobalt, tungsten, or copper.

Although illustrated with respect to device structure 1070 being a thin film capacitor, methods 900 may be extended for use to fabricate other device architectures such as deep trench capacitor 600, multiple capacitor stacked memory device 800, FeFETs, FTJs, or others.

FIG. 11 illustrates exemplary systems employing an IC die having a defect compensation layer on a ferroelectric hafnium oxide-based layer, in accordance with some embodiments. The system may be a mobile computing platform 1105 and/or a data server machine 1106, for example. Either may employ a memory cell, capacitor, FeFET, FTJ or the like having an FE material stack as described elsewhere herein. Server machine 1106 may be any commercial server, for example including any number of high-performance computing platforms disposed within a rack and networked together for electronic data processing, which in the exemplary embodiment includes an IC die assembly 1150 with an IC die assembly including a multi-layer FE material stack as described elsewhere herein. Mobile computing platform 1105 may be any portable device configured for each of electronic data display, electronic data processing, wireless electronic data transmission, or the like. For example, mobile computing platform 1105 may be any of a tablet, a smart phone, a laptop computer, etc., and may include a display screen (e.g., a capacitive, inductive, resistive, or optical touchscreen), a chip-level or package-level integrated system 1110, and a battery 1115. Although illustrated with respect to mobile computing platform 1105, in other examples, chip-level or package-level integrated system 1110 and a power supply/battery 1115 may be implemented in a desktop computing platform, an automotive computing platform, an internet of things platform, or the like. As discussed below, in some examples, the disclosed systems may include a sub-system 1160 such as a system on a chip (SOC) or an integrated system of multiple ICs, which is illustrated with respect to mobile computing platform 1105.

Whether disposed within integrated system 1110 illustrated in expanded view 1120 or as a stand-alone packaged device within data server machine 1106, sub-system 1160 may include memory circuitry and/or processor circuitry 1140 (e.g., RAM, a microprocessor, a multi-core microprocessor, graphics processor, etc.), a power management integrated circuit (PMIC) 1130, a controller 1135, and a radio frequency integrated circuit (RFIC) 1125 (e.g., including a wideband RF transmitter and/or receiver (TX/RX)). As shown, one or more IC dice, such as memory circuitry and/or processor circuitry 1140 may be assembled and implemented such that one or more have a multi-layer FE material stack as described herein. In some embodiments, RFIC 1125 includes a digital baseband and an analog front end module further comprising a power amplifier on a transmit path and a low noise amplifier on a receive path). Functionally, PMIC 1130 may perform battery power regulation, DC-to-DC conversion, etc., and so has an input coupled to power supply/battery 1115, and an output providing a current supply to other functional modules. As further illustrated in FIG. 11, in the exemplary embodiment, RFIC 1125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1140 may provide memory functionality for sub-system 1160, high level control, data processing and the like for sub-system 1160. In alternative implementations, each of the SOC modules may be integrated onto separate ICs coupled to a package substrate, interposer, or board.

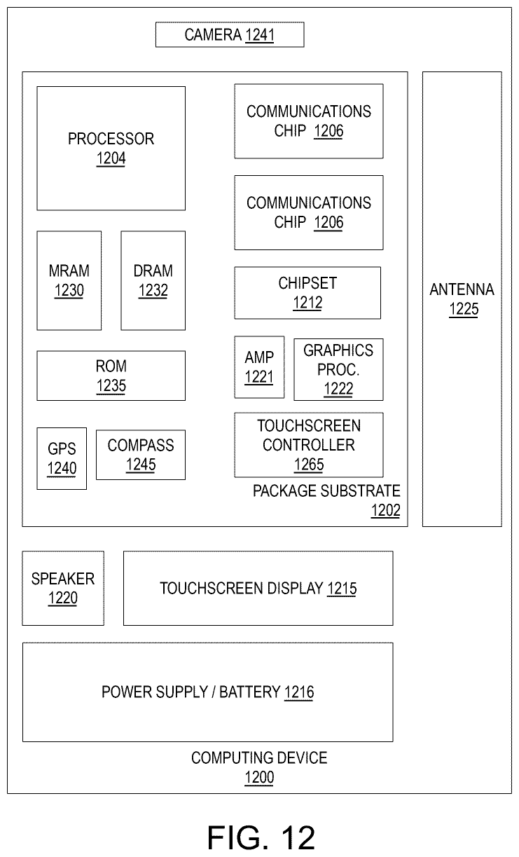

FIG. 12 is a functional block diagram of an electronic computing device 1200, in accordance with some embodiments. For example, device 1200 may, via any suitable component therein, employ a multi-layer FE material stack in accordance with any embodiments described elsewhere herein. Device 1200 further includes a motherboard or package substrate 1202 hosting a number of components, such as, but not limited to, a processor 1204 (e.g., an applications processor). Processor 1204 may be physically and/or electrically coupled to package substrate 1202. In some examples, processor 1204 is within an IC assembly that includes a multi-layer FE material stack as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1206 may also be physically and/or electrically coupled to the package substrate 1202. In further implementations, communication chips 1206 may be part of processor 1204. Depending on its applications, computing device 1200 may include other components that may or may not be physically and electrically coupled to package substrate 1202. These other components include, but are not limited to, volatile memory (e.g., DRAM 1232), non-volatile memory (e.g., ROM 1235), flash memory (e.g., NAND or NOR), magnetic memory (MRAM 1230), a graphics processor 1222, a digital signal processor, a crypto processor, a chipset 1212, an antenna 1225, touchscreen display 1215, touchscreen controller 1265, power supply/battery 1216, audio codec, video codec, power amplifier 1221, global positioning system (GPS) device 1240, compass 1245, accelerometer, gyroscope, speaker 1220, camera 1241, and mass storage device (such as hard disk drive, solid-state drive (SSD), compact disk (CD), digital versatile disk (DVD), and so forth, or the like.

Communication chips 1206 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1206 may implement any of a number of wireless standards or protocols, including, but not limited to, those described elsewhere herein. As discussed, computing device 1200 may include a plurality of communication chips 1206. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first electrode and a second electrode, a first layer between the first electrode and second the electrode, the first layer comprising hafnium and oxygen, and a second layer between the first electrode and the first layer, wherein the first layer is on the second layer, and wherein the second layer comprises a non-stoichiometric compound of oxygen and one of boron, thorium, tantalum, or carbon.

In one or more second embodiments, further to the first embodiments, the non-stoichiometric compound has a stoichiometric deficiency of oxygen relative to the one of boron, thorium, tantalum, or carbon.

In one or more third embodiments, further to the first or second embodiments, the non-stoichiometric compound comprises not less than 40 percent boron and not more than 55 percent oxygen.

In one or more fourth embodiments, further to the first through third embodiments, the non-stoichiometric compound comprises not less than 28 percent tantalum and not more than 65 percent oxygen.

In one or more fifth embodiments, further to the first through fourth embodiments, the first electrode is a top electrode, and the top electrode is on the second layer.

In one or more sixth embodiments, further to the first through fifth embodiments, the apparatus further comprises a third layer between the second electrode and the first layer, wherein the first layer is on the third layer, and wherein the third layer comprises a non-stoichiometric compound of oxygen and one of boron, thorium, tantalum, or carbon.

In one or more seventh embodiments, further to the first through sixth embodiments, the second layer and the third layer each comprise oxygen and one of boron or tantalum.

In one or more eighth embodiments, further to the first through seventh embodiments, the apparatus further comprises a third layer on the second electrode, wherein the first layer is on the third layer, and wherein the third layer comprises oxygen and one of titanium, aluminum, vanadium, tantalum, silicon, or molybdenum.

In one or more ninth embodiments, further to the first through eighth embodiments, the first layer further comprises zirconium.

In one or more tenth embodiments, further to the first through ninth embodiments, the first electrode or the second electrode comprises titanium and nitrogen, tantalum and nitrogen, niobium and nitrogen, ruthenium, tungsten, or molybdenum.

In one or more eleventh embodiments, further to the first through tenth embodiments, an integrated circuit (IC) die comprises the first electrode, the second electrode, and the second layer, the apparatus further comprising a power supply coupled to the IC die.

In one or more twelfth embodiments, an apparatus comprises a first electrode and a second electrode, a ferroelectric material between the first electrode and second the electrode, the ferroelectric material comprising hafnium and oxygen, and a non-stoichiometric material between the ferroelectric material and the first electrode, the non-stoichiometric material comprising oxygen and one of boron, thorium, tantalum, or carbon, wherein the non-stoichiometric material has a stoichiometric deficiency of oxygen relative to the one of boron, thorium, tantalum, or carbon.

In one or more thirteenth embodiments, further to the twelfth embodiments, the non-stoichiometric material comprises not less than 40 percent boron and not more than 55 percent oxygen, or the non-stoichiometric material comprises not less than 28 percent tantalum and not more than 65 percent oxygen.

In one or more fourteenth embodiments, further to the twelfth or thirteenth embodiments, the first electrode is a top electrode and the top electrode is on the non-stoichiometric material.

In one or more fifteenth embodiments, further to the twelfth through fourteenth embodiments, the apparatus further comprises a second non-stoichiometric material on the second electrode, wherein the ferroelectric material is on the second non-stoichiometric material, the second non-stoichiometric material comprising oxygen and one of boron, thorium, tantalum, or carbon, wherein the second non-stoichiometric material has a stoichiometric deficiency of oxygen relative to the one of boron, thorium, tantalum, or carbon.

In one or more sixteenth embodiments, further to the twelfth through fifteenth embodiments, an integrated circuit (IC) die comprises the first electrode, the second electrode, the ferroelectric material, and the non-stoichiometric material, the apparatus further comprising a power supply coupled to the IC die.

In one or more seventeenth embodiments, a method comprises forming a ferroelectric material layer adjacent a first electrode, the ferroelectric material layer comprising hafnium and oxygen, forming a first layer on the ferroelectric material layer, the first layer comprising a non-stoichiometric compound of oxygen and one of boron, thorium, tantalum, or carbon, and forming a second electrode on the first layer.

In one or more eighteenth embodiments, further to the seventeenth embodiments, the non-stoichiometric compound comprises not less than 40 percent boron and not more than 55 percent oxygen, or the non-stoichiometric compound comprises not less than 28 percent tantalum and not more than 65 percent oxygen.

In one or more nineteenth embodiments, further to the seventeenth or eighteenth embodiments, said forming the ferroelectric material layer and said forming the first layer comprises atomic layer deposition of the ferroelectric material layer and the first layer within a continuously sealed process chamber.

In one or more twentieth embodiments, further to the seventeenth through nineteenth embodiments, the method further comprises forming a second layer on the first electrode, the second layer comprising a non-stoichiometric compound of oxygen and one of boron, thorium, tantalum, or carbon, wherein the ferroelectric material layer is formed on the second layer.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first electrode and a second electrode;
a first layer between the first electrode and second the electrode, the first layer comprising hafnium and oxygen; and
a second layer between the first electrode and the first layer, wherein the first layer is on the second layer, and wherein the second layer comprises a non-stoichiometric compound of oxygen and one of boron, thorium, tantalum, or carbon.

2. The apparatus of claim 1, wherein the non-stoichiometric compound has a stoichiometric deficiency of oxygen relative to the one of boron, thorium, tantalum, or carbon.

3. The apparatus of claim 1, wherein the non-stoichiometric compound comprises not less than 40 percent boron and not more than 55 percent oxygen.

4. The apparatus of claim 1, wherein the non-stoichiometric compound comprises not less than 28 percent tantalum and not more than 65 percent oxygen.

5. The apparatus of claim 1, wherein the first electrode is a top electrode, and the top electrode is on the second layer.

6. The apparatus of claim 5, further comprising:
a third layer between the second electrode and the first layer, wherein the first layer is on the third layer, and wherein the third layer comprises a non-stoichiometric compound of oxygen and one of boron, thorium, tantalum, or carbon.

7. The apparatus of claim 6, wherein the second layer and the third layer each comprise oxygen and one of boron or tantalum.

8. The apparatus of claim 5, further comprising:
a third layer on the second electrode, wherein the first layer is on the third layer, and wherein the third layer comprises oxygen and one of titanium, aluminum, vanadium, tantalum, silicon, or molybdenum.

9. The apparatus of claim 1, wherein the first layer further comprises zirconium.

10. The apparatus of claim 1, wherein the first electrode or the second electrode comprises titanium and nitrogen, tantalum and nitrogen, niobium and nitrogen, ruthenium, tungsten, or molybdenum.

11. The apparatus of claim 1, wherein an integrated circuit (IC) die comprises the first electrode, the second electrode, and the second layer, the apparatus further comprising a power supply coupled to the IC die.

12. An apparatus, comprising
a first electrode and a second electrode;
a ferroelectric material between the first electrode and second the electrode, the ferroelectric material comprising hafnium and oxygen; and
a non-stoichiometric material between the ferroelectric material and the first electrode, the non-stoichiometric material comprising oxygen and one of boron, thorium, tantalum, or carbon, wherein the non-stoichiometric material has a stoichiometric deficiency of oxygen relative to the one of boron, thorium, tantalum, or carbon.

13. The apparatus of claim 12, wherein the non-stoichiometric material comprises not less than 40 percent boron and not more than 55 percent oxygen, or the non-stoichiometric material comprises not less than 28 percent tantalum and not more than 65 percent oxygen.

14. The apparatus of claim 12, wherein the first electrode is a top electrode and the top electrode is on the non-stoichiometric material.

15. The apparatus of claim 14, further comprising:
a second non-stoichiometric material on the second electrode, wherein the ferroelectric material is on the second non-stoichiometric material, the second non-stoichiometric material comprising oxygen and one of boron, thorium, tantalum, or carbon, wherein the second non-stoichiometric material has a stoichiometric deficiency of oxygen relative to the one of boron, thorium, tantalum, or carbon.

16. The apparatus of claim 12, wherein an integrated circuit (IC) die comprises the first electrode, the second electrode, the ferroelectric material, and the non-stoichiometric material, the apparatus further comprising a power supply coupled to the IC die.

17. A method, comprising:
forming a ferroelectric material layer adjacent a first electrode, the ferroelectric material layer comprising hafnium and oxygen;
forming a first layer on the ferroelectric material layer, the first layer comprising a non-stoichiometric compound of oxygen and one of boron, thorium, tantalum, or carbon; and
forming a second electrode on the first layer.

18. The method of claim 17, wherein the non-stoichiometric compound comprises not less than 40 percent boron and not more than 55 percent oxygen, or the non-stoichiometric compound comprises not less than 28 percent tantalum and not more than 65 percent oxygen.

19. The method of claim 17, wherein said forming the ferroelectric material layer and said forming the first layer comprises atomic layer deposition of the ferroelectric material layer and the first layer within a continuously sealed process chamber.

20. The method of claim 19, further comprising:
forming a second layer on the first electrode, the second layer comprising a non-stoichiometric compound of oxygen and one of boron, thorium, tantalum, or carbon, wherein the ferroelectric material layer is formed on the second layer.
